(19) United States
(12) Patent Application Publication
(10) Pub. No.: US 2026/0229870 A1
(43) Pub. Date: Aug. 6, 2026

(54) GROUND FAULT CIRCUIT INTERRUPTER AND DETECTION METHOD FOR THE SAME

(71) Applicant: SCHNEIDER ELECTRIC INDUSTRIES SAS, Rueil Malmaison (FR)

(72) Inventors: Bo WANG, Shenzhen (CN); Dahai ZHANG, Shenzhen (CN); Lei YANG, Shenzhen (CN); Chunjing HAO, Shenzhen (CN); Yonggang WANG, Shenzhen (CN)

(21) Appl. No.: 19/149,397

(22) PCT Filed: Jan. 17, 2024
(86) PCT No.: PCT/CN2024/072828

§ 371 Date: Jul. 18, 2025

(30) Foreign Application Priority Data
Jan. 18, 2023 (CN) 202310086007.9

(51) Int. Cl. H02H 3/16; G01R 15/04; G01R 19/00; G01R 31/52; G01R 31/54; H02H 3/04

(52) U.S. Cl. CPC H02H 3/16; G01R 15/04; G01R 19/0084; G01R 31/52; G01R 31/54; H02H 3/04

(57) ABSTRACT

Embodiments of the present disclosure relate to a ground fault circuit interrupter and a detection method for the same. The ground fault circuit interrupter comprises a ground fault circuit interruption switch, wherein when the ground fault circuit interrupter is connected to a power lines, the ground fault circuit interruption switch is coupled in series to the power lines, and the ground fault circuit interrupter comprises: a first drive circuit configured to drive the ground fault circuit interruption switch to open when being energized; a second drive circuit configured to drive the ground fault circuit interruption switch to close when being energized; and a controller configured to: in response to receiving a trigger signal for closing the ground fault circuit interruption switch, determine a state of the first drive circuit; and in response to determining that the first drive circuit is in a normal state, send to the second drive circuit a first connection signal to control the second drive circuit to switch on to close the ground fault circuit interruption switch; in response to determining that the first drive circuit is in an OFF state, not send the first connecting signal to the second drive circuit, thereby not energizing the second drive circuit. The solution according to embodiments of the present disclosure can eliminate safety hazards and ensure safety in electricity use.

This application claims priority to a Chinese patent application for an invention having Application No. 202310086007.9 and entitled “GROUND FAULT CIRCUIT INTERRUPTER AND DETECTION METHOD FOR THE SAME” filed on Jan. 18, 2023, the disclosure of which is incorporated herein by reference in its entirety.

### FIELD

Embodiments of the present disclosure in general relate to electrical protection equipment, and more specifically to a ground fault circuit interrupter and a detection method for the same.

### BACKGROUND

Ground Fault Circuit Interrupter (GFCI) is extensively applied as a safety protection device. The GFCI, when in use, controls open/closed state of a ground fault circuit interruption switch through solenoids. If the solenoids are broken, the ground fault circuit interruption switch may still be closed in response to reception of a reset signal. However, in case of current leakage, the ground fault circuit interruption switch could not be disconnected, which may cause safety hazards.

One currently known solution is to allow the ground fault circuit interruption switch to close only when the solenoids functional normally via a mechanical approach. However, the mechanical approach is complicated in structure and its stability and reliability also need to improve.

### SUMMARY

One object of the present disclosure is to provide a ground fault circuit interrupter and a detection method for the same, to at least partly solve the above problem and other potential problems.

In a first aspect, embodiments of the present disclosure provide a ground fault circuit interrupter comprising a ground fault circuit interruption switch, wherein when the ground fault circuit interrupter is connected to a power lines, the ground fault circuit interruption switch is coupled in series to the power lines, and the ground fault circuit interrupter comprises: a first drive circuit configured to drive the ground fault circuit interruption switch to open when being energized; a second drive circuit configured to drive the ground fault circuit interruption switch to close when being energized; and a controller configured to: in response to receiving a trigger signal for closing the ground fault circuit interruption switch, determine a state of the first drive circuit; and in response to determining that the first drive circuit is in a normal state, send to the second drive circuit a first connection signal to control the second drive circuit to be energized to close the ground fault circuit interruption switch; in response to determining that the first drive circuit is in an OFF state, not send the first connecting signal to the second drive circuit, thereby not energizing the second drive circuit.

In the above embodiments, by determining the state of the first drive circuit before the ground fault circuit interruption switch is closed, it is decided whether to close the ground fault circuit interruption switch in accordance with the state of the first drive circuit, so as to avoid the situation where the ground fault circuit interruption switch could not be opened in case of current leakage after the ground fault circuit interruption switch is closed, so as to ensure safety in electricity use.

In some embodiments, the first drive circuit includes a first solenoid and a first controllable switching device connected in series with the first solenoid; the controller includes a first controller and a second controller; the first controller is configured to monitor a state of the first solenoid and send to a control terminal of the first controllable switching device a second connection signal for switching on the first controllable switching device in response to determining an open circuit fault occurring in the first solenoid; and the second controller is coupled to a control terminal of the first controllable switching device and configured to not send the first connection signal to the second drive circuit in response to detecting the second connection signal on a control terminal of the first controllable switching device; and send the first connection signal to the second drive circuit in response to not detecting the second connection signal on a control terminal of the first controllable switching device.

In the above embodiments, the first controller monitors a state of the first solenoid and sends to a control terminal of the first controllable switching device a second connection signal for switching on the first controllable switching device in response to determining an open circuit fault occurring in the first solenoid, to prevent the second controller from sending the first connection signal to the second drive circuit. Accordingly, it is ensured that the second controller is allowed to send the first connection signal to the second drive circuit to switch on the second drive circuit only when the first solenoid functions normally.

In some embodiments, the ground fault circuit interrupter also comprises an alarm circuit; the first drive circuit includes a first solenoid; the controller includes a first controller and a second controller, and the first controller and the second controller are coupled to the alarm clock; the first controller is configured to monitor a state of the first solenoid and send an alarm signal to the alarm circuit in response to determining an open circuit fault occurring in the first solenoid; and the second controller is configured to not send the first connection signal to the second drive circuit in response to detecting the alarm signal on the alarm circuit, and send the first connection signal to the second drive circuit in response to not detecting the alarm signal on the alarm circuit.

In the above embodiments, the first controller sends an alarm signal to the alarm circuit in response to determining an open circuit fault occurring in the first solenoid, such that the users can know the failure in the ground fault circuit interrupter in time and adopt corresponding measures accordingly; and the second controller can only send the first connection signal to the second drive circuit when no alarm signal is detected, to avoid the situation where circuit leakage occurs after the ground fault circuit interruption switch is closed, and the ground fault circuit interruption switch could not be opened, and ensure safety in electricity use.

In some embodiments, the second drive circuit includes a second solenoid and a second controllable switching device connected in series with the second solenoid; the second controllable switching device is configured to switch on in response to receiving the first connection signal on its control terminal, so as to energize the second solenoid.

In the above embodiments, the second solenoid is connected in series with the second controllable switching device to conveniently and reliably control the state of the second solenoid.

In some embodiments, the alarm circuit includes a light-emitting device; the light-emitting device is configured to emit light in response to receiving the alarm signal.

In the above embodiments, by including a light-emitting device in the alarm circuit, the users are reminded of the failure in the ground fault circuit interrupter in a striking way, so as to adopt corresponding measures.

In some embodiments, the first controller is configured to determine a state of alternating currents in a positive half cycle; and the second controller is configured to determine a state of alternating currents in a positive half cycle from the first controller.

In the above embodiments, the second controller is configured to determine a state of alternating currents in a positive half cycle from the first controller, so as to know a time node for the positive/negative half cycle of the alternating currents, thereby sending corresponding control signals in respective positive or negative half cycles during a self-inspection process.

In some embodiments, the ground fault circuit interrupter further comprises: a voltage dividing circuit coupled to the second drive circuit and the second controller and configured to divide a supply voltage provided by a firing line of the power lines; the second controller is configured to determine whether an open circuit or a short circuit fault occurs in the second drive circuit based on a voltage output by the voltage dividing circuit.

In the above embodiments, a voltage dividing circuit is configured to divide the voltage of the drive circuit (especially key electronic devices in the drive circuit) and it is determined whether a failure occurs in the drive circuit by detecting whether the corresponding divided voltage is identical to the divided voltage of the drive circuit under a normal state. As such, it is automatically and efficiently detected whether a failure occurs in the drive circuit for driving the ground fault circuit interruption switch to act in the current ground fault circuit interrupter, such that the users may maintain or replace the failing ground fault circuit interrupter in time to eliminate safety hazards.

In some embodiments, the second solenoid is coupled between a firing line of the power lines and the second controllable switching device, the second controllable switching device being coupled between the second solenoid and the ground; wherein the voltage dividing circuit includes a voltage dividing resistor having a first terminal coupled to a connecting point on a connecting line between the second solenoid and the second controllable switching device and a second terminal coupled to the ground, and wherein the second controller is coupled to a first terminal of the voltage dividing resistor and configured to detect a voltage at a first terminal of the voltage dividing resistor and determine that an open circuit fault occurs in the second solenoid and/or a short circuit fault occurs in the second controllable switching device in response to determining a voltage at a first terminal of the voltage dividing resistor exceeding a first predetermined threshold interval.

In the above embodiments, normally, key electronic elements in the drive circuit include solenoids and controllable switching devices. The voltage dividing resistor of the voltage dividing circuit is connected between the solenoid and the controllable switching device, to as to determine an open circuit fault in the solenoid and/or a short circuit fault in the controllable switching device, respectively.

In some embodiments, wherein the voltage dividing circuit also comprises a first switch connected in series with the voltage dividing resistor and a control terminal of the first switch is coupled to the second controller and configured to be controlled by the second controller, and wherein the second controller is configured to: control the first switch to close when alternating currents in the power lines are in a positive half cycle state.

In the above embodiments, the divided voltages are symmetrical when the alternating currents are in the positive half cycle and the negative half cycle. As such, it is only required to detect the divided voltage in the positive half cycle, to enhance detection efficiency. In addition, a switch is configured to control the execution of the detection, thereby enhancing detection flexibility.

In some embodiments, wherein the voltage dividing circuit also comprises a voltage source and a second switch coupled between the connecting point and the voltage source; wherein a control terminal of the second switch is coupled to the second controller and the second controller is configured to: control the second switch to close when alternating currents in the power lines are in a negative cycle state, so as to enable the voltage dividing resistor to divide voltage of the voltage source.

In the above embodiments, when the alternating currents are in the negative cycle state, the alternating currents could not be transmitted to the controllable switching device. Therefore, a voltage source is provided to supply power to the voltage dividing detection circuit and the controllable switching device, thereby separately detecting whether a failure occurs in the controllable switching device.

In some embodiments, the second controller is configured to: control the second controllable switching device to remain in a cut-off state when the second switch is in a closed state, detect a voltage at a first terminal of the voltage dividing resistor, and determine that a short circuit fault occurs in the second controllable switching device in response to determining a voltage at a first terminal of the voltage dividing resistor exceeding a second predetermined threshold interval.

In the above embodiments, the voltage dividing resistor and the controllable switching device are coupled in parallel between the voltage source and the ground, such that the voltage across the controllable switching device is identical to the voltage across the voltage dividing resistor. The controllable switching device in the cutoff state may be considered to have an infinitely great resistance, such that the voltage across the divided voltage approximates to the voltage of the voltage source. However, if a short circuit fault occurs in the controllable switching device, the voltage across the divided voltage would reduce remarkably. Therefore, in case that the divided voltage exceeds the second predetermined threshold interval, it is determined that a short circuit fault occurs in the controllable switching device.

In some embodiments, the second controller is also configured to: control the second controllable switching device to enter an ON state when the second switch is closed, detect a voltage at a first terminal of the voltage dividing resistor, and determine that an open circuit fault occurs in the second controllable switching device in response to determining a voltage at a first terminal of the voltage dividing resistor exceeding a third predetermined threshold interval.

In the above embodiments, the controllable switching device in ON state is considered to be equivalent to an ON diode, i.e., having a small voltage drop, such that the voltage across the divided voltage approximates to a voltage drop of the controllable switching device. If an open circuit fault occurs in the controllable switching device, the voltage across the divided voltage would approximate to the voltage of the voltage source. Therefore, when the divided voltage exceeds the third predetermined threshold interval, it is determined that an open circuit fault occurs in the controllable switching device.

In some embodiments, the first switch includes an NPN-type transistor and a PNP-type transistor; an emitter of the NPN-type transistor is grounded; a collector of the NPN-type transistor is coupled to a base of the PNP-type transistor; a base of the NPN-type transistor is coupled to the second controller; a collector of the PNP-type transistor is coupled to the first terminal; and an emitter of the PNP-type transistor is coupled to the connecting point.

In the above embodiments, the NPN-type transistor and the PNP-type transistor may be equivalent to a transistor; when the NPN-type transistor is controlled by the controller, the NPN-type transistor and the PNP-type transistor can be switched on or cut off simultaneously. Meanwhile, the conduction speed is accelerated by setting an NPN-type transistor and a PNP-type transistor.

In some embodiments, the voltage dividing circuit also includes a diode and at least one resistor, wherein an anode of the diode is coupled to an emitter of the PNP-type transistor and a cathode of the diode is adapted to couple to the connecting point, and wherein at least one resistor is connected in parallel across the diode.

In the above embodiments, when the alternating currents are in the positive half cycle state, at least one resistor is set for further voltage division as the supply voltage of the firing line is relatively high. As a result, the voltage across the voltage dividing resistor would not be too high to cause damages to the controller. On the other side, when the alternating currents are in the negative cycle state, the voltage of the voltage source is relatively small. By providing a diode connected in parallel with the at least one resistor, the currents provided by the voltage source are transmitted directly to the controllable switching device via the diode, and the voltage would not be made too small on account of the voltage division by the at least one resistor.

In some embodiments, the second controller is configured to periodically detect whether a short circuit and/or open circuit fault occurs in the second drive circuit.

In the above embodiments, the fault detection is executed periodically, such that the service life of the drive circuit of the ground fault circuit interrupter is monitored without manual labor.

In some embodiments, the second controller is configured to issue an alarm signal in response to determining that a short circuit and/or open circuit fault occurs in the second drive circuit.

In the above embodiments, the users are notified in time via the alarm to avoid dangers.

In some embodiments, the ground fault circuit interrupter also comprises: a zero-crossing detection circuit coupled to the power lines and configured to: detect a state of alternating currents in the power lines, to determine that the alternating currents are in a positive half cycle or a negative half cycle state; and send a signal indicating a state of the alternating currents to the controller.

In some embodiments, the ground fault circuit interrupter also comprises: a sensor configured to sense changes of currents in the power lines, and send to the first controller a current leakage indicating signal indicating current leakage of the power lines in response to changes of the currents exceeding a predetermined value; the first controller is configured to control the first drive circuit to drive the ground fault circuit interruption switch to open based on the current leakage indicating signal.

In the above embodiments, the sensor is provided to sense changes of currents in the power lines, such that a current leakage indicating signal indicating current leakage of the power lines can be sent to the first controller in time in case of current leakage. As a result, the first controller can timely control the first drive circuit to drive the ground fault circuit interruption switch to open, thereby ensuring safety in electricity use.

In accordance with a second aspect of the present disclosure, there is also provided a detection method for a ground fault circuit interrupter, the ground fault circuit interrupter comprising a ground fault circuit interruption switch, a first drive circuit and a second drive circuit, wherein when the ground fault circuit interrupter is connected to a power lines, the ground fault circuit interruption switch is coupled in series to the power lines, and wherein the first drive circuit is configured to drive the ground fault circuit interruption switch to open when being energized; the second drive circuit is configured to drive the ground fault circuit interruption switch to close when being energized; and the method comprises: in response to receiving a trigger signal for closing the ground fault circuit interruption switch, determining a state of the first drive circuit; and in response to determining that the first drive circuit is in a normal state, sending to the second drive circuit a first connection signal to control the second drive circuit to switch on to close the ground fault circuit interruption switch; and in response to determining that the first drive circuit is in an OFF state, not sending the first connecting signal to the second drive circuit, thereby not energizing the second drive circuit.

In the above embodiments, by determining the state of the first drive circuit before the ground fault circuit interruption switch is closed, it is decided whether to close the ground fault circuit interruption switch in accordance with the state of the first drive circuit, so as to avoid the situation where the ground fault circuit interruption switch could not be opened in case of current leakage after the ground fault circuit interruption switch is closed, so as to ensure safety in electricity use. Moreover, it is efficiently detected whether a failure exists in the drive circuit for opening the ground fault circuit interruption switch in the ground fault circuit interrupter, so as to timely discover and eliminate safety hazards.

The summary is intended to introduce a selection of concepts in a simplified form, and they will be further described below in the detailed description. The summary is not intended to identify key features or essential features of the claimed subject matter, nor is it intended to limit the scope of the claimed subject matter.

### BRIEF DESCRIPTION OF THE DRAWINGS

FIG. 1 illustrates a schematic diagram of a ground fault circuit interrupter in accordance with one embodiment of the present disclosure;

FIG. 2 illustrates a schematic diagram of a ground fault circuit interrupter in accordance with another embodiment of the present disclosure; and

FIG. 3 illustrates a detection method for a ground fault circuit interrupter in accordance with one embodiment of the present disclosure.

In each drawing, same or corresponding reference signs indicate same or corresponding composites.

### DETAILED DESCRIPTION OF EMBODIMENTS

Principles of the present disclosure are now explained with reference to various example embodiments shown in the drawings. It should be appreciated that description of those embodiments is merely to enable those skilled in the art to better understand and further implement the present disclosure and is not intended for limiting the scope disclosed herein in any manners. It should be noted similar or same reference signs can be used in the drawings where feasible, and similar or same reference signs can represent similar or same functions. Those skilled in the art will easily understand from the following description that alternative embodiments of the structure and/or method described in the text can be adopted without deviating from the principles of the present invention described herein

As used herein, the term “includes” and its variants are to be read as open-ended terms that mean “includes, but is not limited to.” Unless the context clearly indicates otherwise, the term “or” is to be read as “and/or”. The term “based on” is to be read as “based at least in part on.” The terms “one example embodiment” and “one embodiment” are to be read as “at least one example embodiment.” The term “a further embodiment” is to be read as “at least a further embodiment.” The terms “first”, “second” and so on can refer to same of different objects.

As mentioned above, the GFCI, when in use, controls open/closed state of a ground fault circuit interruption switch through solenoids. If the solenoids are broken, the ground fault circuit interruption switch may still be closed in response to reception of a reset signal. However, in case of current leakage, the ground fault circuit interruption switch could not be disconnected; even if an LED alarm is provided, it is insufficient to well protect the users to use electricity safely. One currently known solution is to mechanically ensure that the closing of the ground fault circuit interruption switch is allowed only when the solenoids function normally. In this solution, a mechanical switch is linked to an unlocking mechanism and the mechanical switch is checked before being closed. If there is nothing wrong with the mechanical switch, the unlocking mechanism is opened to allow closing the circuit; otherwise, the unlocking mechanism does not open and the circuit could not be closed. However, the mechanical solution is complicated in structure and performs poorly in stability and reliability. Therefore, an improved solution is in need to enhance stability and reliability.

Embodiments of the present disclosure provide an improved solution. In some embodiments of the present disclosure, there is provided a ground fault circuit interrupter comprising a ground fault circuit interruption switch. When the ground fault circuit interrupter is connected to power lines, the ground fault circuit interruption switch is coupled in series to the power lines. The ground fault circuit interrupter comprises: a first drive circuit, a second drive circuit and a controller. The first drive circuit, when energized, drives the ground fault circuit interruption switch to open. The second drive circuit, when energized, drives the ground fault circuit interruption switch to close. Upon receiving a trigger signal for closing the ground fault circuit interruption switch, the controller determines a state of the first drive circuit. When it is determined that the first drive circuit is in a normal state, a first connection signal is sent to the second drive circuit to control the second drive circuit to close the ground fault circuit interruption switch. However, when it is determined that the first drive circuit in an open state, the first connection signal is not sent to the second drive circuit, so that the second drive circuit is not energized.

The solution according to embodiments of the present disclosure can avoid the situation where the ground fault circuit interruption switch could not be opened in case of current leakage after the ground fault circuit interruption switch is closed, so as to ensure safety in electricity use.

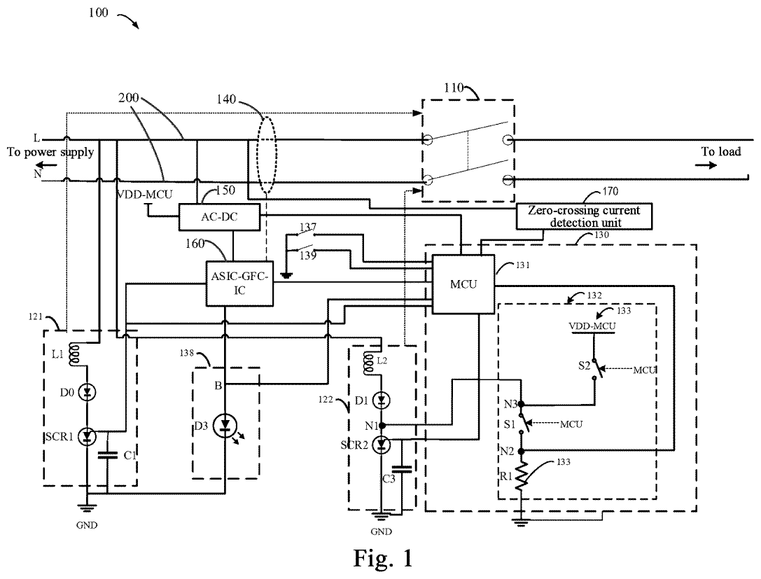

The ground fault circuit interrupter according to example embodiments of the present disclosure is to be described in details below with reference to FIGS. 1-3.

First, FIG. 1 illustrates a schematic diagram of the ground fault circuit interrupter 100 according to one embodiment of the present disclosure. As shown in FIG. 1, the ground fault circuit interrupter 100 is connected in a power lines 200. The power lines 200 may include a firing line L and a null line N. The firing line L and the null line N are connected to a power source such as public grid on one side and connected to a load or electric equipment on the other side. Accordingly, the electric power may be transmitted from the power source to the load via the power lines 200 to supply power to the electric equipment. Although the power lines 200 shown in FIG. 1 is a single-phase system, the ground fault circuit interrupter 100 according to embodiments of the present disclosure is not limited to the single-phase system and may be applied to a multi-phase system, such as three-phase system.

In some cases, for example when a person or a conductive object accidentally touches the firing line L, the power lines 200 may leak currents, which currents may flow through the person and cause personal injury. For this, the power lines 200 is provided with the ground fault circuit interrupter 100. The ground fault circuit interrupter 100 provides leakage protection function for the power lines 200 and the electric equipment connected to the power lines 200, so as to protect safety of the person and the device when current leakage or grounded short circuit occurs in the user device or the circuit.

The ground fault circuit interrupter 100 may include a ground fault circuit interruption switch 110, which ground fault circuit interruption switch 110 is coupled in series to the power lines 200 when the ground fault circuit interrupter is connected to the power lines 200. The ground fault circuit interruption switch 110 may open in case of a current leakage of the power lines 200, to ensure safety in electricity use. After the current leakage fault is ruled out, it is required to reset the ground fault circuit interruption switch 110 to continue playing the protective role. For this, a reset button 137 in the ground fault circuit interrupter 100 may be operated to send a trigger signal to the controller, to restore the ground fault circuit interruption switch 110 to a closed state.

The ground fault circuit interrupter 100 comprises a first drive circuit 121, a second drive circuit 122 and a controller. The first drive circuit 121, when energized, may drive the ground fault circuit interruption switch 110 to open. The second drive circuit 122, when energized, may drive the ground fault circuit interruption switch 110 to close. The controller is used to control the first drive circuit 121 and the second drive circuit 122 to close, so as to control the ground fault circuit interruption switch 110 to trip or close to reset. The ground fault circuit interrupter 100 also may comprise an AC-DC power supply unit 150 or other suitable elements, to provide a proper power supply voltage to the ground fault circuit interrupter 100.

As shown in FIG. 1, in some embodiments, the first drive circuit 121 may include a first solenoid L1 and a first controllable switching device SCR1 connected in series with the first solenoid L1. The first solenoid L1 may be energized when the first controllable switching device SCR1 is switched on to produce a magnetic field, which interacts with a permanent magnet in the ground fault circuit interruption switch 110 to open the ground fault circuit interruption switch 110. The second drive circuit 122 may include a second solenoid L2 and a second controllable switching device SCR2 connected in series with the second solenoid L2, wherein the second controllable switching device SCR2 is switched on in response to receiving on its control terminal a first connection signal, to energize the second solenoid L2. The magnetic field generated by energizing the second solenoid L2 interacts with a permanent magnet in the ground fault circuit interruption switch 110, to close the ground fault circuit interruption switch 110.

The controller includes a first controller 160 configured to send a signal to the first controllable switching device SCR1 in the first drive circuit 121 in case of a current leakage in the power lines 200 to switch on the first controllable switching device SCR1, thereby energizing the first solenoid L1 and further driving the ground fault circuit interruption switch 110 to open. For this, the ground fault circuit interrupter 100 also comprises a sensor 140. The sensor 140 is configured to sense a change of the currents in the power lines 200 and send to the first controller 160 a current leakage indicating signal indicating current leakage of the power lines 200 in response to the change of the currents exceeding a predetermined value, such that the first controller 160 is made aware of the current leakage in the power lines 200.

The first controller 160 is also configured to monitor the state of the first solenoid L1 and send a second connection signal for switching on the first controllable switching device SCR1 to a control terminal of the first controllable switching device SCR1 in response to determining an open circuit fault occurring in the first solenoid L1. Since the controls over the ground fault circuit interruption switch 110 by the first drive circuit 121 and the second drive circuit 122 are mutually exclusive, the second controller 131, upon detecting the second connection signal for switching on the first controllable switching device SCR1, may deem that the first drive circuit 121 is in ON state and would not control the switch-on of the second drive circuit 122. Therefore, it is ensured that the second controller 131 would not actively drive the second drive circuit 122 to close when the first solenoid L is in OFF state, so as not to close the ground fault circuit interruption switch 110.

Those skilled in the art know that the first controller 160 may monitor whether an open circuit fault occurs in the first solenoid L1 through various ways. For example, it is determined whether an open circuit fault occurs in the first solenoid L1 by monitoring currents in the first solenoid L1 and/or voltage across the first solenoid L1. Embodiments of the present disclosure are not restricted to this and various alternatives may be provided.

The controller also includes a second controller 131. The second controller 131 is configured to send a signal to the second controllable switching device SCR2 in the second drive circuit 122 to switch the second controllable switching device SCR2 on when the current leakage fault in the power lines 200 is removed and it is required to restore normal power supply, such that the second solenoid L2 is energized to further drive the ground fault circuit interruption switch 110 to close and reset. For this, the ground fault circuit interrupter 100 also includes a reset button 137 coupled to the second controller 131. When it is required to reset the ground fault circuit interruption switch 110, the rest button 137 is pressed to generate a reset signal.

After receiving the reset signal from the reset button 137, the second controller 131 first initiates the detection over the first drive circuit 121 instead of driving the second controllable switching device SCR2 in the second drive circuit to close. When it is confirmed that the first drive circuit 121 is normal, the second controllable switching device SCR2 is closed to close the ground fault circuit interruption switch 110, so as to avoid the case where the ground fault circuit interruption switch 110 could not be disconnected when the current leakage occurs again.

In order to confirm whether the first drive circuit 121 is normal before the second controllable switching device SCR2 is driven to close, the second controller 131 may be coupled to a control terminal of the first controllable switching device SCR1. As stated above, when it is determined that an open circuit fault occurs in the first solenoid L, the first controller 160 would send to the control terminal of the first controllable switching device SCR1 a second connection signal for switching on the first controllable switching device SCR1. Accordingly, the second controller 131 may determine whether the first solenoid L or the first drive circuit 212 is normal by monitoring the signal on the control terminal of the first controllable switching device SCR1. If the second controller 131 detects the second connection signal on the control terminal of the first controllable switching device SCR1, it is confirmed that a fault occurs in the first solenoid L1 or the first drive circuit 121. In such case, the first connection signal is not sent to the second controllable switching device SCR2 in the second drive circuit 122, i.e., the second controllable switching device SCR2 is not driven to switch on.

In some embodiments, the ground fault circuit interrupter 100 also may include an alarm circuit 138 to which both the first controller 160 and the second controller 131 are coupled. The first controller 160 may monitor the state of the solenoid L1 and send an alarm signal to the alarm circuit 138 when it is determined that an open circuit fault occurs in the first solenoid L1. The alarm circuit 138 may include a light-emitting device D3, which light-emitting device D3 emits light in response to receiving the alarm signal. The second controller 131 determines that a fault occurs in the first solenoid L or the first drive circuit 121 by detecting an alarm signal on the alarm circuit 138 (e.g., anode of the light-emitting device D3, i.e., B point), so as not to send the first connection signal to the second controllable switching device SCR2 in the second drive circuit 122, i.e., the second controllable switching device SCR2 is not driven to close.

In addition, to ensure safety in electricity use, the users also may manually press a test button 139 to test whether the first drive circuit 121 can normally open the ground fault circuit interruption switch 110. The test button 139, when being pressed manually, may send a trigger signal to the second controller 131. After receiving the trigger signal, the second controller 131 sends a control signal to the first controllable switching device SCR1 to switch it on, thereby testing whether the first drive circuit 121 is normal and whether the ground fault circuit interruption switch 110 can be smoothly opened.

In some embodiments, the first controller 160 may be Application Specific Integrated Circuit (ASIC). The second controller 131 may be a control device or a processing device with computation and processing power, e.g., Microcontroller Unit (MCU) or Digital Signal Processor (DSP). Embodiments of the present disclosure are not restricted to this. In some embodiments, the first controller 160 and the second controller 131 also may be implemented in other forms, e.g., in analog circuit and/or digital circuit forms, or a combination thereof.

As shown in FIG. 1, in some embodiments, the ground fault circuit interrupter 100 also may include a voltage dividing detection circuit 130. The voltage dividing detection circuit 130 may include the second controller 131 and a voltage dividing circuit 132. The voltage dividing circuit 132 is coupled to the second drive circuit 122 and the second controller 131 and is configured to divide the power supply voltage provided by a firing line of the power lines 200. The second controller 131 may determine whether an open circuit fault and/or a short circuit fault occurs in the second drive circuit 122 based on the voltage output by the voltage dividing circuit 132.

In some embodiments, the voltage dividing circuit 132 also may be independent of the ground fault circuit interrupter 100. For example, the voltage dividing circuit 132 may be separated from the ground fault circuit interrupter 100 and is attached or linked to the ground fault circuit interrupter 100 and the power lines 200 when it is required to detect or test the ground fault circuit interrupter 100. Embodiments of the present disclosure also may be implemented in this way.

In some embodiments, the second controller 131 may compare the detected divided voltage of the voltage dividing circuit 132 with a divided voltage of the second drive circuit 122 in the normal state, to determine whether the second drive circuit fails. For this, a predetermined threshold interval, e.g., +10% of the normal divided voltage value, may be obtained based on a normal divided voltage of the voltage dividing circuit 132 under the normal state of the drive circuit 122 and a given tolerance. If the divided voltage detected by the second controller 131 is within a predetermined threshold interval, it is determined that the second drive circuit 122 is normal. On the contrary, if the divided voltage is outside the predetermined threshold interval, it is determined that an open circuit fault and/or a short circuit fault occurs in the drive circuit 122. In some embodiments, the second controller 131 may issue an alarm signal when it is determined that an open circuit fault and/or a short circuit fault occurs in the second drive circuit 122.

Implementations of the voltage dividing circuit 132 of the ground fault circuit interrupter 100 according to embodiments of the present disclosure may be further described below.

As shown in FIG. 1, the second drive circuit 122 includes a second solenoid L2, a first diode D1 and a second controllable switching device SCR2 (e.g., silicon controlled switching device) sequentially connected in series between the firing line L and the ground GND. The second solenoid L2 is coupled between the firing line of the power lines 200 and the second controllable switching device SCR2, wherein the second controllable switching device SCR2 is coupled between the second solenoid L2 and the ground GND. An anode of the first diode D1 is coupled to the firing line L and a cathode of the first diode D1 is coupled to an anode of the second controllable switching device SCR2. A cathode of the second controllable switching device SCR2 is coupled to the ground GND and a control node of the second controllable switching device SCR2 is coupled to the second controller 131. Normally, the second solenoid L2 and the second controllable switching device SCR2 are considered as key components in the second drive circuit 122. Therefore, failure detection involves detecting whether an open circuit fault occurs in the second solenoid L2 and whether an open circuit fault or a short circuit fault occurs in the second controllable switching device SCR2.

In accordance with some embodiments of the present disclosure, the voltage dividing circuit 132 is coupled to a connecting point N1 on a connecting line between the second solenoid L2 and the second controllable switching device SCR2. Specifically, the voltage dividing circuit 132 includes a first switch S1 and a voltage dividing resistor R1 coupled in series between the connecting point N1 and the ground GND. The control terminal of the first switch S1 is coupled to the second controller 131 and can be controlled by the second controller 131 to close or open. The second controller 131 controls the first switch S1 to close when the alternating currents in the power lines 200 are in the positive half cycle state. The first terminal N2 of the voltage dividing resistor R1 is coupled to the connecting point N1 on the connecting line between the second solenoid L2 and the second controllable switching device SCR2, and the second terminal of the voltage dividing resistor R1 is coupled to the ground GND; and wherein the second controller 131 is coupled to the first terminal N2 of the voltage dividing resistor R1 and is configured to detect a voltage at the first terminal N2 of the voltage dividing resistor R1. In addition, in response to determining the voltage at the first terminal N2 of the voltage dividing resistor R1 exceeding a first predetermined threshold interval, it is determined that an open circuit fault occurs in the second solenoid L2 and/or a short circuit fault occurs in the second controllable switching device SCR2.

Due to conduction characteristics of the first diode D1, the currents flow from the firing line L to the connecting point N1 and then to the voltage dividing circuit 132 at the connecting point N1 when the alternating currents in the firing line L are in a positive half-cycle state. However, when the alternating currents in the firing line L are in a negative cycle, the alternating currents provided by the firing line L could not flow through the second drive circuit 122 and the voltage dividing circuit 132. For this, the second controller 131 is also coupled to a zero-crossing current detection unit 170 of the ground fault circuit interrupter 100 and receives from the zero-crossing current detection unit 170 a signal indicating a state of the alternating current, such that the second controller 131 can know the state of the alternating current and different fault detection mechanisms may be performed under different states of the alternating current.

When the alternating currents in the firing line L are in the positive half cycle state, the second controller 131 may execute the first fault detection mechanism and control the first switch S1 to close, such that the currents are transmitted to the voltage dividing resistor R1 through the first switch S1. As such, the second solenoid L2 and the voltage dividing resistor R1 are connected in series between the firing line L and the ground GND and divide the supply voltage provided by the firing line L. The voltage dividing circuit 132 is coupled to the second controller 131 at the first terminal N2 of the voltage dividing resistor R1. Accordingly, the second controller 131 can detect the voltage at the first terminal N2 of the voltage dividing resistor R1. Then, the second controller 131 compares the detected divided voltage with the first predetermined threshold interval. Here, the first predetermined threshold interval may be the detected divided voltage of the voltage dividing circuit 132 during the normal operation of the second drive circuit 122 or may be a threshold interval obtained based on the divided voltage value calculated as a function of the voltage dividing characteristics of the circuit in combination with a given tolerance on the basis of the normal divided voltage value.

When the detected voltage is within the first predetermined threshold interval, the second controller 131 determines that the second solenoid L2 functions normally without having an open circuit fault. However, if an open circuit fault occurs in the second solenoid L2, the currents of the firing line L could not pass through the second solenoid L2. As such, there are no currents in the line where the second solenoid L2 and the voltage dividing resistor R1 are arranged. Therefore, the divided voltage at the first terminal N2 of the voltage dividing resistor R1 is zero. Besides, if the second controllable switching device SCR2 is short circuited, the connecting point N1 is directly coupled to the ground GND. In such case, the first terminal N2 of the voltage dividing resistor R1 is directly coupled to the connecting point N1, such that the voltage detected by the second controller 131 is a ground GND voltage, i.e., zero. Hence, when the detected voltage is outside the first predetermined threshold interval, the second controller 131 determines that the second solenoid L2 is open-circuited or the second controllable switching device SCR2 is short-circuited.

When the alternating currents in the firing line L are in the negative cycle, the alternating currents provided by the firing line L could not flow through the second drive circuit 122 and the voltage dividing circuit 132 due to the first diode D1. For this, the voltage dividing circuit 132 also includes a voltage source 133 to provide voltage and further includes a second switch S2 to control the connection of the voltage source 133. The control terminal of the second switch S2 is coupled to the second controller 131 and controlled by the same. The voltage source 133, for example, may be the voltage provided by the power supply unit 150 same as that provided to the second controller 131. One end of the second switch S2 is coupled to the voltage source 133 and a further end thereof is coupled to a switch connecting point N3 on a connecting line between the connecting point N1 and the first switch S1.

When the alternating currents in the firing line L are in the negative cycle state, the second controller 131 executes the second fault detection mechanism, controls the first switch S1 and the second switch S2 to close, and controls the second controllable switching device SCR2 to cut off, such that the voltage dividing resistor R1 is coupled between the voltage source 133 and the ground GND, the voltage dividing resistor R1 divides the voltage of the voltage source 133 and the second controllable switching device SCR2 is likewise coupled between the voltage source 133 and the ground GND. Afterwards, the second controller 131 detects the divided voltage at the first terminal N2 of the voltage dividing resistor R1 and compares the detected divided voltage with a second predetermined threshold interval.

In the second fault detection, the potentials on the connecting point N1, the switch connecting point N3 and the first terminal N2 of the voltage dividing resistor R1 are the same. If the second controllable switching device SCR2 is fault free, it may be considered to have an approximately infinite resistance under the cut-off state. As such, the potential at the connecting point N1 should approximate to the voltage of the voltage source 133, so that the voltage at the first terminal N2 also approximates to the voltage of the voltage source 133. If a short circuit fault occurs in the second controllable switching device SCR2, the voltage dividing resistor R1 may be deemed as being short circuited. Therefore, the potential at the first terminal N2 is zero. In other words, if the second controller 131 determines that the divided voltage is outside the second predetermined threshold interval, the second terminal 131 determines that a short circuit fault occurs in the second controllable switching device SCR2.

In order to determine whether an open circuit fault occurs in the second controllable switching device SCR2, the second controller 131 also may execute a third fault detection mechanism when the alternating currents in the firing line L are in the negative cycle state, controls the first switch S1 and the second switch S2 to close and controls the second controllable switching device SCR2 to switch on. Similarly, as a result, the voltage dividing resistor R1 is coupled between the voltage source 133 and the ground GND and the second controllable switching device SCR2 is also coupled between the voltage source 133 and the ground GND. Then, the second controller 131 detects the divided voltage at the first terminal N2 of the voltage dividing resistor R1 and compares the divided voltage with a third predetermined threshold interval.

In the third fault detection, the potentials on the connecting point N1, the switch connecting point N3 and the first terminal N2 of the voltage dividing resistor R1 are the same. If the second controllable switching device SCR2 is fault free, the voltage at the connecting point N1 under the ON state may be considered as a voltage drop of the second controllable switching device SCR2, such that the potential at the first terminal N2 is also the voltage drop of the second controllable switching device SCR2. If an open circuit fault occurs in the second controllable switching device SCR2, the circuit where the second controllable switching device SCR2 is disposed may be considered as an open circuit, such that the voltage at the first terminal N2 approximates to the voltage of the voltage source 133. In other words, if the second controller 131 determines that the divided voltage is outside the third predetermined threshold interval, the second terminal 131 determines that an open circuit fault occurs in the second controllable switching device SCR2.

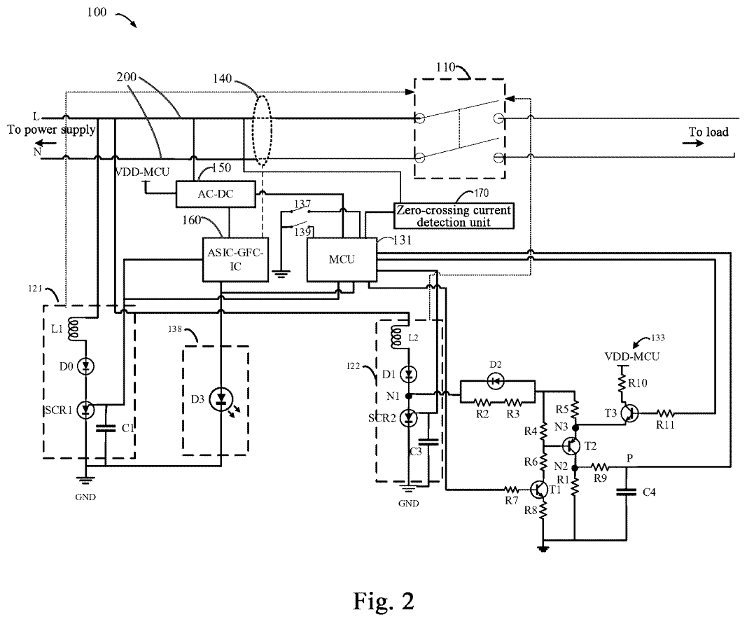

The ground fault circuit interrupter 100 according to embodiments of the present disclosure is further described below with reference to FIG. 2. FIG. 2 illustrates a schematic diagram of the ground fault circuit interrupter according to a further embodiment of the present disclosure. In comparison to FIG. 1, FIG. 2 illustrates the implementations of the ground fault circuit interrupter 100 and the voltage dividing detection circuit 130 in more details.

As shown in FIG. 2, the first switch S1 of the voltage dividing circuit 132 in the voltage dividing detection circuit 130 may include an NPN-type transistor T1 and a PNP-type transistor T2. An emitter of the NPN-type transistor T1 is coupled to the ground GND via a resistor R8. A collector of the NPN-type transistor T1 is coupled to a base of the PNP-type transistor T2 via a resistor R6. The base of the NPN-type transistor T1 is coupled to a second controller 131 via a resistor R7. A collector of the PNP-type transistor T2 is coupled to the first terminal N2. An emitter of the PNP-type transistor T2 is adapted to couple to the connecting point N1 via a resistor R5. A base of the PNP-type transistor T2 is adapted to couple to the connecting point N1 via a resistor R4. As such, the NPN-type transistor T1 and the PNP-type transistor T2 may be equivalent to a Darlington transistor, which is controlled by the second controller 131.

Besides, the second switch S2 of the voltage dividing circuit 132 may include an NPN-type transistor T3. A collector of the NPN-type transistor T3 is coupled to a voltage source VDD-MCU via a resistor R10 and an emitter of the NPN-type transistor T3 is coupled to the switch connecting point N3. A base of the NPN-type transistor T3 is coupled to the second controller 131 via a resistor R11 and controlled by the second controller 131. Here, if the NPN-type transistor T3 fails, a hierarchical structure of the first switch can divide the voltage, to avoid damages to the second controller 131 when an over-high voltage is connected to it. Therefore, the service life of the circuit is extended.

Different from the embodiment shown in FIG. 1, the voltage dividing circuit 132 also includes a second diode D2 and a second resistor R2 and a third resistor R3 coupled in series. An anode of the second diode D2 is coupled to the emitter of the PNP-type transistor T2 and a cathode of the second diode D2 is coupled to the connecting point N1. The resistor R2 and the third resistor R3 are coupled in parallel across the second diode D2.

In some embodiments, when the alternating currents are in the positive cycle state, the supply voltage of the firing line L is relatively high, and the voltage at the connecting point N1 is about 90V. The voltage division is further performed by setting the second resistor R2, the third resistor R3 and the voltage dividing resistor R1, such that the voltage across the voltage dividing resistor R1 would not be too high to cause damage to the controller. On the other side, when the alternating currents are in the negative cycle state, the voltage of the voltage source VDD-MCU is small. By providing the second diode D2 connected in parallel with the second resistor R2 and the third resistor R3, the direct currents provided by the voltage source VDD-MCU are directly transmitted to the second controllable switching device SCR2 via the second diode D2 and the voltage would not be made too small due to the voltage division by the second resistor R2 and the third resistor R3.

A resistor R9 is connected between the first terminal N2 of the voltage dividing resistor R1 and the second controller 131, and a grounded capacitance C4 is further connected to the connecting circuit between the resistor R9 and the second controller 131. The resistor R9 and the capacitance C4 may be formed into a filter structure, to filter the voltage signal detected at the first terminal N2 of the second controller 131.

It should be appreciated that the first switch including the NPN-type transistor T1 and the PNP-type transistor T2 may correspond to the first switch S1 in FIG. 1 and the second switch including the NPN-type transistor T3 may correspond to the second switch S2 in FIG. 2. Accordingly, the voltage dividing circuit 132 in FIG. 2 can execute the first, second and third fault detection mechanisms as described with reference to FIG. 1 together under the control of the second controller 131.

Principles of the above described first, second and third fault detection mechanisms are to be further described in details below.

In the first fault detection mechanism, the alternating currents provided by the firing line L are in the positive cycle state. The second controller 131 controls the NPN-type transistor T1 to switch on, so as to switch on the PNP-type transistor T2 as well. In such case, the currents start from the firing line L and then go through the second solenoid L2 and the first diode D1 to reach the connecting point N1. Afterwards, from the connecting point N1, the currents flow through the resistors R2 and R3 and then are divided into two parallel branches. In one branch, the currents flow from the resistor R3 to go through the resistors R4, R6 and R8 until reaching the ground GND. In another branch, the currents flow through the resistor R5 and the voltage dividing resistor R1 and reach the ground GND. When the second drive circuit 122 is fault free, the voltage across the voltage dividing resistor R1 is as follows:

$${V}_{R 1} = \frac{{V}_{N 1} * \frac{( R 5 + R 1 ) ( R 4 + R 6 + R 8 )}{R 5 + R 1 + R 4 + R 6 + R 8}}{( R 2 + R 3 ) + \frac{( R 5 + R 1 ) ( R 4 + R 6 + R 8 )}{R 5 + R 1 + R 4 + R 6 + R 8}} * \frac{R 1}{R 5 + R 1} \qquad ( 1 )$$

Where V_{R1} is the voltage at the first terminal N2 of the voltage dividing resistor R1, and V_{N1} is the voltage at the connecting point N1. In some embodiments, by adjusting the resistance values of respective resistors, the V_{R1} may have a voltage below a withstand voltage of the second controller 131. For example, the V_{R1} may be 0.8V and accordingly acts as a first predetermined threshold. If the second controller 131 detects that a value of V_{R1} is within a predetermined threshold interval of [0.72, 0.88], the second controller 131 may determine that the second drive circuit 122 is fault free. If the second controller 131 detects that a value of V_{R1} is outside a predetermined threshold interval of [0.72, 0.88], e.g., the value of V_{R1} is zero, the second controller 131 may determine that the second solenoid L2 of the second drive circuit 122 is open-circuited or the second controllable switching device SCR2 is short-circuited.

In the second fault detection mechanism, the alternating currents provided by the firing line L are in the negative cycle state. The second controller 131 controls the NPN-type transistor T1 and the NPN-type transistor T3 to switch on and controls the second controllable switching device SCR2 to cut off. In such case, starting from the voltage source VDD-MCU, the currents go through the resistor R10 and the NPN-type transistor T3 to reach the switch connecting point N3. Afterwards, from the switch connecting point N3, the currents are divided into two parallel branches. In one branch, the currents flow through the resistor R5, the second diode D2 and the second controllable switching device SCR2 until reaching the ground GND. In another branch, the currents flow through the PNP-type transistor T2 and the voltage dividing resistor R1 and reach the ground GND. When the second drive circuit 122 is fault free, the second controllable switching device SCR2 is considered to have an infinitely great resistance, such that the voltage V_{N3} at the switch connecting point N3 is as follows:

$${V}_{N 3} = {V}_{VDD} - {V}_{T 3} \qquad ( 2 )$$

Wherein V_{VDD} is the voltage of the voltage source VDD-MCU and V_{T3} indicates a voltage drop of the NPN-type transistor T3.

Accordingly, the voltage V_{R1} at the first terminal N2 is:

$${V}_{R 1} = {V}_{N 3} - {V}_{T 2} = {V}_{VDD} - {V}_{T 3} - {V}_{T 2} \qquad ( 3 )$$

Wherein V_{VDD} is the voltage of the voltage source VDD-MCU and V_{T2} indicates a voltage drop of the PNP-type transistor T3.

However, if the second controllable switching device SCR2 is short circuited, the voltage V_{N3} at the switch connecting point N3 is:

$${V}_{N 3} = {V}_{D 2}$$

Wherein V_{D2} is a voltage drop of the second diode D2. The voltage drop of the second diode D2 is much smaller than the voltage of the voltage source VDD-MCU.

Therefore, the voltage V_{R1} at the first terminal N2 is as follows:

$${V}_{R 1} = {V}_{N 3} - {V}_{T 2} = {V}_{D 2} - {V}_{T 2} \qquad ( 5 )$$

In some embodiments, V_{VDD} may be 3.3V and V_{T3} and V_{T2} may be 0.3V. As such, V_{R1} should be 2.7V as calculated and may serve as a second predetermined threshold. If the second controller 131 detects that a value of V_{R1} is within a second predetermined threshold interval of [2.43V, 2.97V], the second controller 131 may determine that the second drive circuit 122 is fault free. If the second controller 131 detects that a value of V_{R1} is outside a predetermined threshold interval of [2.43V, 2.97V], e.g., the value of V_{R1} is quite small, the second controller 131 may determine that the second controllable switching device SCR2 of the second drive circuit 122 is short-circuited.

In the third fault detection mechanism, the alternating currents provided by the firing line L are in the negative cycle state. The second controller 131 controls the NPN-type transistor T1 and the NPN-type transistor T3 to switch on and controls the second controllable switching device SCR2 to turn on. When the second drive circuit 122 is fault free, the switch-on of the second controllable switching device SCR2 is considered as a diode, such that the voltage V_{N3} at the switch connecting point N3 is as follows:

$${V}_{N 3} = {V}_{SCR} + {V}_{D 2} \qquad ( 6 )$$

Wherein the V_{SCR} refers to a voltage drop of the second controllable switching device SCR2 when being switched on.

Accordingly, the voltage V_{R1} at the first terminal N2 is:

$${V}_{R 1} = {V}_{N 3} - {V}_{T 2} = {V}_{SCR} + {V}_{D 2} - {V}_{T 2} \qquad ( 7 )$$

However, if the second controllable switching device SCR2 is open-circuited, there is no electricity formed in the branch where the second controllable switching device SCR2 is positioned, such that the currents flow from the voltage source VDD-MCU to the ground GND through the resistor R10 and the voltage dividing resistor R1. In such case, the voltage dividing resistor R1 and the resistor R10 divide the voltage and the voltage V_{R1} at the first terminal N2 is as follows:

$${V}_{R 1} = ( {V}_{VDD} - {V}_{T 3} - {V}_{T 2} ) * \frac{R 1}{R 1 + R 10} \qquad ( 8 )$$

In some embodiments, V_{SCR} and V_{D2} may be 0.7V respectively and V_{T2} may be 0.3V. On this basis, the V_{R1} should be 1.1V as calculated and may act as a second predetermined threshold. If the second controller 131 detects that a value of V_{R1} is within a second predetermined threshold interval of [0.99V, 1.21V], the second controller 131 may determine that the second drive circuit 122 is fault free. If the second controller 131 detects that a value of V_{R1} is outside a predetermined threshold interval of [0.99V, 1.21V], the second controller 131 may determine that the second controllable switching device SCR2 of the second drive circuit 122 is open-circuited.

With the detection mechanisms in the above embodiments, it is effectively detected whether a fault occurs in the first drive circuit 121 for opening the ground fault circuit interruption switch in the ground fault circuit interrupter and the safety hazards are discovered and eliminated in time.

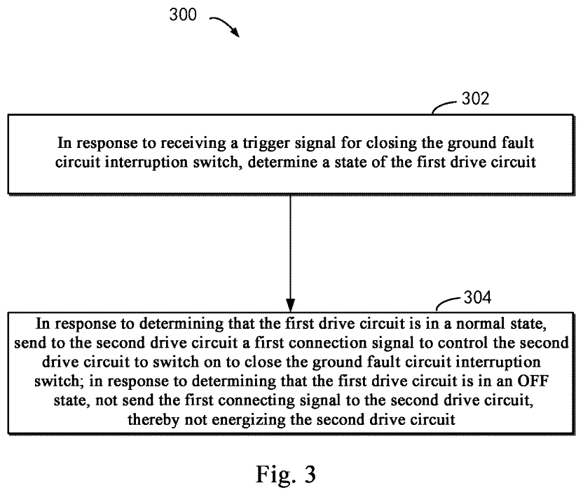

FIG. 3 illustrates a detection method for the ground fault circuit interrupter according to one embodiment of the present disclosure. The ground fault circuit interrupter 100 may comprise a ground fault circuit interruption switch 110, a first drive circuit 121 and a second drive circuit 122. When the ground fault circuit interrupter 100 is connected to the power lines 200, the ground fault circuit interruption switch 110 is coupled in series into the power lines 200, wherein the first drive circuit 121 is configured to drive the ground fault circuit interruption switch 110 to open when being energized; the second drive circuit 122 is configured to drive the ground fault circuit interruption switch 110 to close when being energized. The method comprises: in response to receiving a trigger signal for closing the ground fault circuit interruption switch 110, determining a state of the first drive circuit 121; and in response to determining that the first drive circuit 121 being in a normal state, sending to a second drive circuit 122 a first connection signal to control the second drive circuit 122 to switch on, so as to close the ground fault circuit interruption switch; however, in response to determining that the first drive circuit 121 being in an OFF state, the first connection signal is not sent to the second drive circuit 122 and the second drive circuit 122 is not energized.

In the method according to embodiments of the present disclosure, before the ground fault circuit interruption switch is closed, a state of the first drive circuit is determined; it is decided whether to close the ground fault circuit interruption switch in accordance with the state of the first drive circuit, so as to avoid the situation where the ground fault circuit interruption switch could not be opened in case of current leakage after the ground fault circuit interruption switch is closed, thereby ensuring safety in electricity use.

The claimed technical solution can avoid the situation where the ground fault circuit interruption switch could not be opened in case of current leakage after the ground fault circuit interruption switch is closed and ensures safety in electricity use. In addition, it is effectively detected whether a fault occurs in the drive circuit for opening the ground fault circuit interruption switch in the ground fault circuit interrupter and the safety hazards are discovered and eliminated in time.

Various embodiments of the present disclosure have been described above and the described embodiments are optional embodiments of the present disclosure. The above description is only exemplary rather than exhaustive and is not limited to the embodiments of the present disclosure. Although the claims of the present application are drafted for specific combinations of the features, it should be understood that the scope of the present disclosure also includes explicit or implicit features, or any novel features or any novel combinations of the features, no matter whether the features relate to the same solution in any claims or not. Applicant hereby states that new claims may be drafted for these features and/or combinations thereof in the examination procedure of the present application or any further applications derived from the present application.

The selection of terms in the text aims to best explain principles and actual applications of each embodiment and technical improvements made in the market by each embodiment, or enable those ordinary skilled in the art to understand embodiments of the present disclosure. Many modifications and alterations of the present disclosure are obvious for those skilled in the art. Any modifications, equivalent substitutions and improvements shall be included in the protection scope of the present disclosure as long as they are within the spirit and principle disclosed herein.

1. A ground fault circuit interrupter (100) comprising a ground fault circuit interruption switch (110), wherein when the ground fault circuit interrupter is connected to a power lines (200), the ground fault circuit interruption switch (110) is coupled in series to the power lines (200), and the ground fault circuit interrupter (100) comprises:
a first drive circuit (121) configured to drive the ground fault circuit interruption switch (110) to open when being energized;
a second drive circuit (122) configured to drive the ground fault circuit interruption switch (110) to close when being energized; and
a controller configured to:
in response to receiving a trigger signal for closing the ground fault circuit interruption switch (110), determine a state of the first drive circuit (121); and in response to determining that the first drive circuit (121) is in a normal state, send to the second drive circuit (122) a first connection signal to control the second drive circuit (122) to be energized to close the ground fault circuit interruption switch (110); in response to determining that the first drive circuit (121) is in an OFF state, not send the first connecting signal to the second drive circuit (122), thereby not energizing the second drive circuit (122).

2. The ground fault circuit interrupter (100) according to claim 1, wherein:
the first drive circuit (121) includes a first solenoid (L1) and a first controllable switching device (SCR1) connected in series with the first solenoid (L1);
the controller includes a first controller (160) and a second controller (131),
the first controller (160) is configured to monitor a state of the first solenoid (L1) and send to a control terminal of the first controllable switching device (SCR1) a second connection signal for switching on the first controllable switching device (SCR1) in response to determining an open circuit fault occurring in the first solenoid (L1); and
the second controller (131) is coupled to a control terminal of the first controllable switching device (SCR1) and configured to not send the first connection signal to the second drive circuit (122) in response to detecting the second connection signal on a control terminal of the first controllable switching device (SCR1); and send the first connection signal to the second drive circuit (122) in response to not detecting the second connection signal on a control terminal of the first controllable switching device (SCR1).

3. The ground fault circuit interrupter (100) according to claim 1, wherein:
the ground fault circuit interrupter (100) also comprises an alarm circuit (138);
the first drive circuit (121) includes a first solenoid (L1);
the controller includes a first controller (160) and a second controller (131), and the first controller (160) and the second controller (131) are coupled to the alarm clock (138);
the first controller (160) is configured to monitor a state of the first solenoid (L1) and send an alarm signal to the alarm circuit (138) in response to determining an open circuit fault occurring in the first solenoid (L1); and
the second controller (131) is configured to not send the first connection signal to the second drive circuit (122) in response to detecting the alarm signal on the alarm circuit (138), and send the first connection signal to the second drive circuit (122) in response to not detecting the alarm signal on the alarm circuit (138).

4. The ground fault circuit interrupter (100) according to claim 2, wherein:
the second drive circuit (122) includes a second solenoid (L2) and a second controllable switching device (SCR2) connected in series with the second solenoid (L2);
the second controllable switching device (SCR2) is configured to switch on in response to receiving the first connection signal on its control terminal, so as to energize the second solenoid (L2).

5. The ground fault circuit interrupter (100) according to claim 3, wherein:
the alarm circuit (138) includes a light-emitting device (D3);
the light-emitting device (D3) is configured to emit light in response to receiving the alarm signal.

6. The ground fault circuit interrupter (100) according to claim 1, wherein:
the first controller (160) is configured to determine a state of alternating currents in a positive half cycle; and
the second controller (131) is configured to determine the state of alternating currents in the positive half cycle from the first controller (160).

7. The ground fault circuit interrupter (100) according to claim 4, further comprising:
a voltage dividing circuit (132) coupled to the second drive circuit (122) and the second controller (131) and configured to divide a supply voltage provided by a firing line of the power lines (200);
the second controller (131) is configured to determine whether an open circuit or a short circuit fault occurs in the second drive circuit (122) based on a voltage output by the voltage dividing circuit (132).

8. The ground fault circuit interrupter (100) according to claim 7, wherein:
the second solenoid (L2) is coupled between a firing line of the power lines (200) and the second controllable switching device (SCR2), the second controllable switching device (SCR2) being coupled between the second solenoid (L2) and the ground (GND);
wherein the voltage dividing circuit (132) includes a voltage dividing resistor (R1) having a first terminal (N2) coupled to a connecting point (N1) on a connecting line between the second solenoid (L2) and the second controllable switching device (SCR2) and a second terminal coupled to the ground (GND), and
wherein the second controller (131) is coupled to a first terminal (N2) of the voltage dividing resistor (R1) and configured to detect a voltage at a first terminal (N2) of the voltage dividing resistor (R1) and determine that an open circuit fault occurs in the second solenoid (L2) and/or a short circuit fault occurs in the second controllable switching device (SCR2) in response to determining a voltage at a first terminal (N2) of the voltage dividing resistor (R1) exceeding a first predetermined threshold interval.

9. The ground fault circuit interrupter (100) according to claim 8, wherein the voltage dividing circuit (132) also comprises a first switch (S1) connected in series with the voltage dividing resistor (R1) and a control terminal of the first switch (S1) is coupled to the second controller (131) and configured to be controlled by the second controller (131), and
wherein the second controller (131) is configured to: control the first switch (S1) to close when alternating currents in the power lines (200) are in a positive half cycle state.

10. The ground fault circuit interrupter (100) according to claim 8, wherein the voltage dividing circuit (132) also comprises a voltage source (133) and a second switch (S2) coupled between the connecting point (N1) and the voltage source (133);
wherein a control terminal of the second switch (S2) is coupled to the second controller (131) and the second controller (131) is configured to: control the second switch (S2) to close when alternating currents in the power lines (200) are in a negative cycle state, so as to enable the voltage dividing resistor (R1) to divide voltage of the voltage source (133).

11. The ground fault circuit interrupter (100) according to claim 10, wherein the second controller (131) is configured to: control the second controllable switching device (SCR2) to remain in a cut-off state when the second switch (S2) is in a closed state, detect a voltage at a first terminal (N2) of the voltage dividing resistor (R1), and determine that a short circuit fault occurs in the second controllable switching device (SCR2) in response to determining a voltage at a first terminal (N2) of the voltage dividing resistor (R1) exceeding a second predetermined threshold interval.

12. The ground fault circuit interrupter (100) according to claim 10, wherein the second controller (131) is also configured to:
control the second controllable switching device (SCR2) to enter an ON state when the second switch (S2) is closed, detect a voltage at a first terminal (N2) of the voltage dividing resistor (R1), and determine that an open circuit fault occurs in the second controllable switching device (SCR2) in response to determining the voltage at the first terminal (N2) of the voltage dividing resistor (R1) exceeding a third predetermined threshold interval.

13. The ground fault circuit interrupter (100) according to claim 8, wherein the first switch (S1) includes an NPN-type transistor (T1) and a PNP-type transistor (T2); an emitter of the NPN-type transistor (T1) is grounded; a collector of the NPN-type transistor (T1) is coupled to a base of the PNP-type transistor (T2); a base of the NPN-type transistor (T1) is coupled to the second controller (131); a collector of the PNP-type transistor (T2) is coupled to the first terminal (N2); and an emitter of the PNP-type transistor (T2) is coupled to the connecting point (N3).

14. The ground fault circuit interrupter (100) according to claim 13,
wherein the voltage dividing circuit (132) also includes a diode (D2) and at least one resistor (R2, R3), wherein an anode of the diode (D2) is coupled to the emitter of the PNP-type transistor (T2) and a cathode of the diode (D2) is adapted to couple to the connecting point (N1), and wherein at least one resistor (R2, R3) is connected in parallel across the diode (D2).

15. The ground fault circuit interrupter (100) according to claim 2, wherein the second controller (131) is configured to periodically detect whether a short circuit and/or open circuit fault occurs in the second drive circuit (122).

16. The ground fault circuit interrupter (100) according to claim 2, wherein the second controller (131) is configured to send an alarm signal in response to determining that a short circuit and/or open circuit fault occurs in the second drive circuit (122).

17. The ground fault circuit interrupter (100) according to claim 1, wherein the ground fault circuit interrupter (100) also comprises:
a zero-crossing detection circuit (170) coupled to the power lines (200) and configured to: detect a state of alternating currents in the power lines (200) to determine that the alternating currents are in a positive half cycle or a negative half cycle state;
and send a signal indicating a state of the alternating currents to the controller.

18. The ground fault circuit interrupter (100) according to claim 2, further comprising:
a sensor (140) configured to sense changes of currents in the power lines (200), and send to the first controller (160) a current leakage indicating signal indicating current leakage of the power lines (200) in response to changes of the currents exceeding a predetermined value;
the first controller (160) is configured to control the first drive circuit (121) to drive the ground fault circuit interruption switch (110) to open based on the current leakage indicating signal.

19. A detection method for a ground fault circuit interrupter, the ground fault circuit interrupter (100) comprising a ground fault circuit interruption switch (110), a first drive circuit (121) and a second drive circuit (122), wherein when the ground fault circuit interrupter is connected to a power lines (200), the ground fault circuit interruption switch (110) is coupled in series to the power lines (200), and wherein the first drive circuit (121) is configured to drive the ground fault circuit interruption switch (110) to open when being energized; the second drive circuit (122) is configured to drive the ground fault circuit interruption switch (110) to close when being energized; and the method comprises:
in response to receiving a trigger signal for closing the ground fault circuit interruption switch (110), determining a state of the first drive circuit (121); and
in response to determining that the first drive circuit (121) is in a normal state, sending to the second drive circuit (122) a first connection signal to control the second drive circuit (122) to be energized to close the ground fault circuit interruption switch (110); and in response to determining that the first drive circuit (121) is in an OFF state, not sending the first connecting signal to the second drive circuit (122), thereby not energizing the second drive circuit (122).
